(19) United States
(12) Patent Application Publication
(10) Pub. No.: US 2025/0266403 A1
(43) Pub. Date: Aug. 21, 2025

(54) SLANTED DIE STACKING TO MITIGATE OVERHANG DEFLECTION

(71) Applicant: Micron Technology, Inc., Boise, ID (US)

(72) Inventors: See Hiong LEOW, Singapore (SG); Hong Wan NG, Singapore (SG); Chin Hui CHONG, Singapore (SG); Ling PAN, Singapore (SG); Seng Kim YE, Singapore (SG); Kelvin Aik Boo TAN, Singapore (SG)

(21) Appl. No.: 19/025,283

(22) Filed: Jan. 16, 2025

Related U.S. Application Data
(60) Provisional application No. 63/554,581, filed on Feb. 16, 2024.

(51) Int. Cl. H01L 25/07; H10B 80/00

(52) U.S. Cl. CPC H01L 25/074; H01L 25/071; H01L 2225/06562; H01L 2225/06593; H10B 80/00

(57) ABSTRACT

A semiconductor device assembly includes a circuit substrate including a first substrate surface and a second substrate surface; a wedge structure arranged on the first substrate surface, wherein the wedge structure has a slanted upper surface that is slanted with respect to the first substrate surface; a die stack arranged on the slanted upper surface, wherein the die stack comprises a plurality of dies, wherein the die stack is oriented at an angle corresponding to the slanted upper surface, and wherein the die stack has a first lateral portion coupled to the slanted upper surface and a second lateral portion that overhangs from the slanted upper surface; a package casing disposed over the first substrate surface, wherein the package casing encapsulates the die stack and covers at least part of the first substrate surface; and a plurality of conductive interconnect structures coupled to the second substrate surface.

### CROSS REFERENCE TO RELATED APPLICATION

This Patent application claims priority to U.S. Provisional Patent Application No. 63/554,581, filed on Feb. 16, 2024, and entitled “SLANTED DIE STACKING TO MITIGATE OVERHANG DEFLECTION.” The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to semiconductor chip packages that include a slanted die stack.

### BACKGROUND

A semiconductor package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as via balls, pins, leads, contact pads, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIG. 1 is a diagram of an example apparatus that may be manufactured using techniques described herein.

FIG. 2 is a diagram of a semiconductor device assembly according to one or more implementations.

FIG. 3 is a diagram of an example memory device that may be manufactured using techniques described herein.

FIG. 4 is a flowchart of an example method of forming an integrated assembly or memory device having a slanted die stack.

### DETAILED DESCRIPTION

A die stack may be a vertical stack of two or more dies, with one die arranged on top of another. A die stack typically includes dies that are horizontally stacked on a mounting surface of a circuit substrate. In other words, each die may be arranged in a horizontal orientation relative to the mounting surface. Thus, main surfaces, such as top and bottom surfaces, of each die may be arranged parallel to the mounting surface. Moreover, the die stack may be arranged on a spacer that is attached to the mounting surface. Thus, the spacer may be arranged between the die stack and the mounting surface. The die stack may include an overhanging portion that overhangs or extends from an edge of the spacer.

The overhanging portion may deform by bending, sagging, deflection, or warping, which may result in one or more dies of the die stack cracking and/or developing one or more electrical failures or other defects. For example, upper dies of the die stack may exert pressure on lower dies of the die stack, which may cause the overhanging portion to deflect downward. As more dies are included in the die stack, an amount of pressure exerted on the lower dies may increase. Moreover, as dies become thinner, dies may become more vulnerable to deformation from vertical downward pressure from the upper dies. The deformation may cause one or more defects to develop.

Additionally, the overhanging portion may enable another device, such as another die, to be arranged underneath the overhanging portion. As a result, a number of devices included in a semiconductor device assembly, such as a semiconductor chip package, may be increased without drastically increasing a footprint of the semiconductor device assembly. In some cases, the overhanging portion may deflect downward to an extent that the die stack comes in contact with the device that is arranged underneath the overhanging portion. The contact between the die stack and the device may increase a risk of an electrostatic discharge (ESD) event occurring between the die stack and the device, which may disrupt an operation of one or more dies of the die stack and/or the device. In some cases, an ESD event may result in damage to one or more dies of the die stack and/or damage to the device. Moreover, in some cases, the deformation may cause a warpage of the semiconductor chip package to occur, which may cause electrical failures at a package level.

Some implementations provide a semiconductor device assembly that includes one or more slanted die stacks. A die stack may be slanted on an angle relative to a mounting surface of a circuit substrate. Thus, the die stack may have a raised lateral end arranged at a higher vertical distance from the mounting surface, and a lowered lateral end that is arranged at a lower vertical distance from the mounting surface. In other words, a neutral axis of the die stack may be shifted to a slanted plane instead of a horizontal plane. An overhanging portion of the die stack may include the raised lateral end.

The shift in the neutral axis may result in less warpage at higher temperatures. In addition, the shift in the neutral axis may reduce an amount of downward (e.g., vertical) pressure exerted on lower dies by upper dies of the die stack. As a result, an overhanging portion of the die stack may undergo less deformation, and dies of the die stack may be less likely to develop defects. Moreover, a slanted orientation of the die stack may be used to increase a gap distance between the die stack and a device arranged underneath the die stack. As a result, contact between the die stack and the device may be prevented, and ESD events may be less likely to occur. In addition, bond wires (e.g., gold wires) may be attached to the lowered lateral end of the die stack. Since the lowered lateral end is closer to the mounting surface of the circuit substate, the bond wires may be made shorter than would be possible with a horizontal die stack. Thus, a material cost of the semiconductor device assembly may be reduced due to less material being needed for the shorter bond wires. In addition, a slanted spacer made of a molding material may be used between the die stack and the mounting surface of the circuit substate. The molding material is relatively cheap to use and easy to mold. Thus, the slanted spacer may reduce both material cost and manufacturing time relative to a semiconductor device assembly that may use silicon spacers.

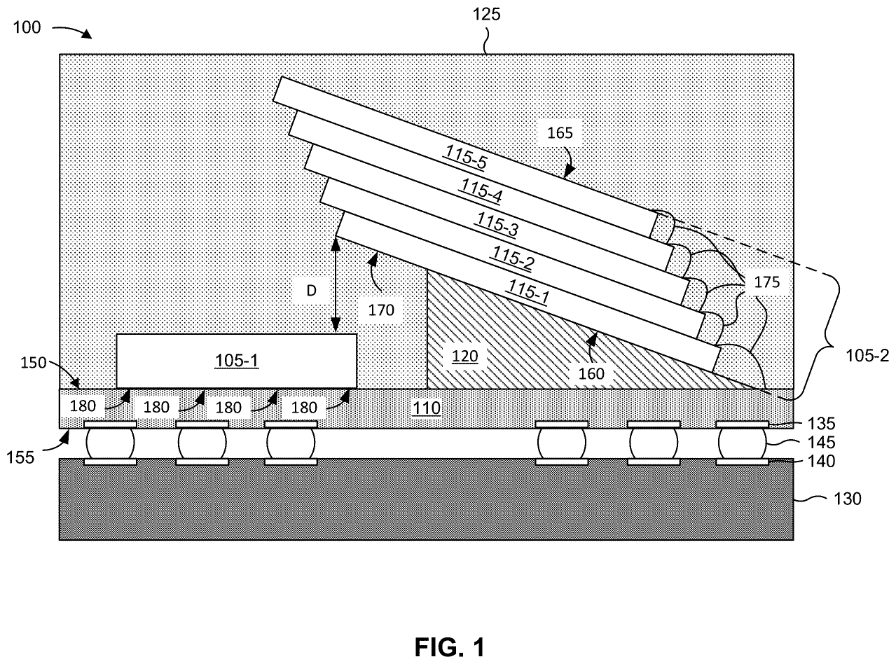

FIG. 1 is a diagram of an example apparatus 100 that may be manufactured using techniques described herein. The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in FIG. 1, the apparatus 100 may include one or more integrated circuits 105, shown as a first integrated circuit 105-1 and a second integrated circuit 105-2, disposed on a substrate 110 (e.g., a circuit substrate). An integrated circuit 105 may include any type of circuit, such as an analog circuit, a digital circuit, a controller (e.g., a microcontroller), a radiofrequency (RF) circuit, a power supply, a power management circuit, an input-output (I/O) chip, an application-specific integrated circuit (ASIC), a field-programmable gate array (FPGA), and/or a memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include a single semiconductor die 115 (sometimes called a die), as shown by the first integrated circuit 105-1. In some implementations, an integrated circuit 105 may include multiple semiconductor dies 115 (sometimes called dies), as shown by the second integrated circuit 105-2, which is shown as including five semiconductor dies 115-1 through 115-5. In some implementations, the first integrated circuit 105-1 may be a microcontroller, such as a memory controller, and the semiconductor dies 115-1 through 115-5 may be memory dies, such as NAND memory dies or DRAM memory dies. Thus, the first integrated circuit 105-1 may be electrically coupled to a plurality of dies of the second integrated circuit 105-2 by conductive traces provided on and/or in the substrate 110. The microcontroller may control one or more data operations and/or memory operations of the semiconductor dies 115-1 through 115-5.

As shown in FIG. 1, for an integrated circuit 105 that includes multiple dies 115, the dies 115 may be stacked on top of each other to form a die stack to reduce a footprint of the apparatus 100. Thus, the second integrated circuit 105-2 may be referred to as a die stack. In some implementations, a spacer 120 may be present between dies 115 that are adjacent to one another in the stack to enable electrical separation and heat dissipation. The stacked dies 115 may include three-dimensional electrical interconnects, such as through-silicon vias (TSVs), to route electrical signals between dies 115. Although the second integrated circuit 105-2105-2 is shown as including five dies 115, an integrated circuit 105 may include a different number of dies 115 (e.g., at least two dies 115). A first die 115-1 (sometimes called a bottom die or a base die) may be disposed on the spacer 120, a second die 115-2 may be disposed on the first die 115-1, and so on.

The dies 115 may be arranged and connected in a shingle-stack configuration to form a shingle stack. In the shingle-stack configuration, die edges of the dies 115 are not aligned, but are instead offset from each other. Thus, each subsequent die of the die stack is offset from a previous die (e.g., a lower die) of the die stack such that an amount of each die of the die stack that overhangs from the spacer 120 increases with each subsequent die. The shingle-stack configuration may provide space for wire bonding near the edges of the dies 115. Although FIG. 1 shows the dies 115 stacked in a shingle stack (e.g., with die edges that are not aligned), in some implementations, the dies 115 may be stacked in a different arrangement, such as a straight stack (e.g., with aligned die edges).

The apparatus 100 may include a casing 125 (e.g., a package casing) that protects internal components of the apparatus 100 (e.g., the integrated circuits 105) from damage and environmental elements (e.g., particles) that can lead to malfunction of the apparatus 100. The casing 125 may be a mold compound, a plastic (e.g., an epoxy plastic), a ceramic, or another type of material depending on the functional requirements for the apparatus 100.

In some implementations, the apparatus 100 may be included as part of a higher-level system (e.g., a computer, a mobile phone, a network device, an SSD, a vehicle, or an Internet of Things device), such as by electrically connecting the apparatus 100 to a circuit board 130, such as a printed circuit board. For example, the substrate 110 may be disposed on the circuit board 130 such that electrical contacts 135 (e.g., bond pads) of the substrate 110 are electrically connected to electrical contacts 140 (e.g., bond pads) of the circuit board 130.

In some implementations, the substrate 110 may be mounted on the circuit board 130 using a plurality of conductive interconnect structures 145, such as solder balls (e.g., arranged in a ball grid array), which may be melted to form a physical and electrical connection between the substrate 110 and the circuit board 130. Additionally, or alternatively, the substrate 110 may be mounted on and/or electrically connected to the circuit board 130 using another type of connector, such as pins or leads. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The interconnections between an integrated circuit 105, the substrate 110, and the circuit board 130 enable the integrated circuit 105 to receive and transmit signals to other components of the apparatus 100 and/or the higher-level system.

The substrate 110 may include a first substrate surface 150 (e.g., a mounting surface) and a second substrate surface 155 arranged opposite to the first substrate surface 150. The spacer 120 may be a wedge structure that is arranged on the first substrate surface 150. The spacer 120 has a slanted upper surface 160 that is slanted with respect to the first substrate surface 150.

The second integrated circuit 105-2 (e.g., the die stack) may be arranged on the slanted upper surface 160 such that the second integrated circuit 105-2 is oriented at an angle corresponding to the slanted upper surface 160. The second integrated circuit 105-2 may have a first lateral portion 165 coupled to the slanted upper surface 160 and may have a second lateral portion 170 that overhangs from the slanted upper surface 160. In other words, the first lateral portion 165 may be in contact with the slanted upper surface 160, and the second lateral portion 170 may extend from an edge of the slanted upper surface 160 such that the second lateral portion 170 hangs over the first substrate surface 150. Moreover, a vertical distance between the second integrated circuit 105-2 and first substrate surface 150 may increase as a lateral distance between the edge of the slanted upper surface 160 to a stack edge of the second lateral portion 170 increases.

The first lateral portion 165 of the second integrated circuit 105-2 may include a lowered lateral end that is arranged at a lower vertical distance from the first substrate surface 150. Conversely, the second lateral portion 170 may include a raised lateral end that is arranged at a higher vertical distance from the first substrate surface 150. Bond wires 175 may be attached to the lowered lateral end of the second integrated circuit 105-2. For example, one or more bond wires 175 may be attached to a lowered lateral end of each die 115, with the bond wire 175 of the first die 115-1 being attached to the first substrate surface 150. The shingle-stack configuration provides space for wire bonding near the edges of the dies 115. Thus, the first die 115-1 may be electrically coupled to the first substrate surface 150. Since the lowered lateral end of the second integrated circuit 105-2 is closer to the first substrate surface 150, the bond wires 175 may be made shorter than would be possible with a horizontal die stack. Thus, a material cost of the apparatus 100 may be reduced due to less material being needed for the shorter bond wires.

As noted above, each subsequent die of the second integrated circuit 105-2 may be offset from a previous, lower die of the second integrated circuit 105-2 such that an amount each die of the die stack that overhangs from the spacer 120 increases with each subsequent die. For example, the first die 115-1 may be arranged on the slanted upper surface 160 of the spacer 120 and may have a first overhang that extends beyond an edge of the slanted upper surface 160. Additionally, the second die 115-2 may be arranged on the first die 115-1 and may have a second overhang that extends beyond the edge of the slanted upper surface 160. The second overhang of the second die 115-2 may extend further from the edge of the slanted upper surface 160 than the first overhang of the first die 115-1. Thus, the second overhang may be larger than the first overhang.

The second lateral portion 170 may extend over a portion of the first integrated circuit 105-1. The second lateral portion 170 and the first integrated circuit 105-1 may be separated by a vertical gap D such that the second integrated circuit 105-2 is not in contact with the first integrated circuit 105-1. The vertical gap D may be sufficiently large to prevent ESD events from occurring between the first integrated circuit 105-1 and the second integrated circuit 105-2. In some implementations, the first integrated circuit 105-1 may have a flip-chip interconnect configuration. For example, the first integrated circuit 105-1 may include electrical contacts 180 that are arranged at a lower main surface of the integrated circuit 105-1. The electrical contacts 180 of the integrated circuit 105-1 may be attached to the first substrate surface 150. As a result, bond wires that may be at risk of coming into contact with the second lateral portion 170 are not needed, and ESD events occurring between the first integrated circuit 105-1 and the second integrated circuit 105-2 may be prevented.

The casing 125 may be disposed over the first substrate surface 150 such that the casing 125 encapsulates the first integrated circuit 105-1 and the second integrated circuit 105-2, and covers at least part of the first substrate surface 150. The plurality of conductive interconnect structures 145 may be coupled to the second substrate surface 155. For example, the plurality of conductive interconnect structures 145 may be attached to the electrical contacts 135 that are arranged at the second substrate surface 155.

As indicated above, FIG. 1 is provided as an example. Other examples may differ from what is described with regard to FIG. 1. The number and arrangement of components shown in FIG. 1 are provided as an example. In practice, there may be additional components, fewer components, different components, or differently arranged components than those shown in FIG. 1.

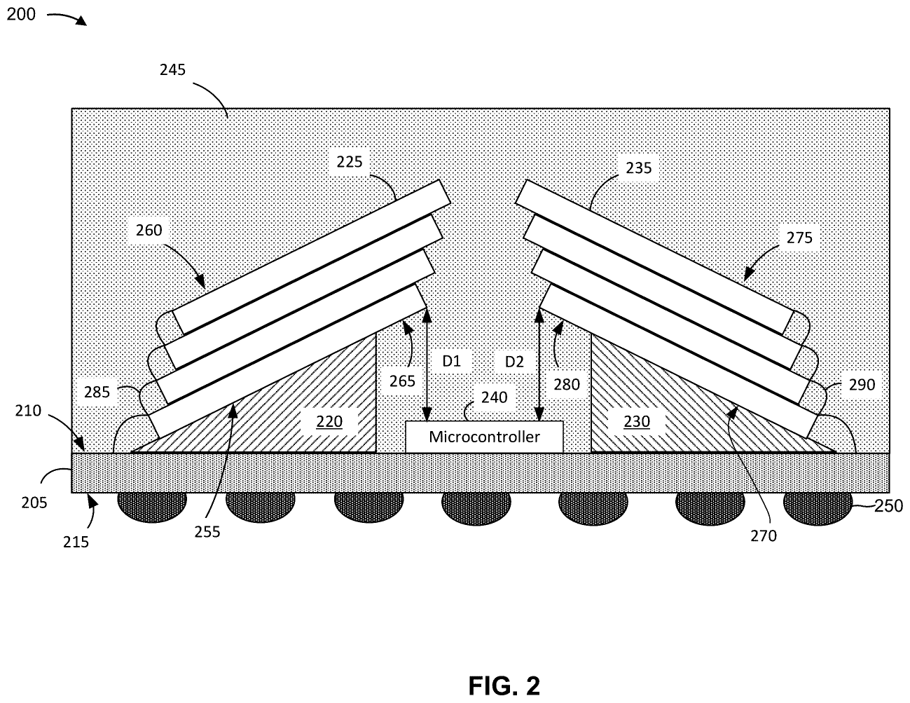

FIG. 2 is a diagram of a semiconductor device assembly 200 according to one or more implementations. The semiconductor device assembly 200 may be similar to the apparatus 100 described in connection with FIG. 1, with the exception that the semiconductor device assembly 200 may include multiple die stacks.

The semiconductor device assembly 200 may include a substrate 205 (e.g., a circuit substrate) that includes a first substrate surface 210 and a second substrate surface 215 arranged opposite to the first substrate surface 210. In addition, the semiconductor device assembly 200 may include a first wedge structure 220, a first die stack 225, a second wedge structure 230, a second die stack 235, a microcontroller 240, a package casing 245, and a plurality of conductive interconnect structures 250.

The first wedge structure 220 may be a slanted spacer arranged on the first substrate surface 210. The first wedge structure 220 may have a first slanted upper surface 255 that is slanted with respect to the first substrate surface 210. The first die stack 225 may be arranged on the first slanted upper surface 255. The first die stack 225 incudes a first plurality of dies and may be oriented at a first angle corresponding to the first slanted upper surface 255. The first die stack 225 may have a first lateral portion 260 coupled to the first slanted upper surface 255, and a second lateral portion 265 that overhangs from the first slanted upper surface 255.

The second wedge structure 230 may be a slanted spacer arranged on the first substrate surface 210. The second wedge structure 230 may have a second slanted upper surface 270 that is slanted with respect to the first substrate surface 210. The second die stack 235 may be arranged on the second slanted upper surface 270. The second die stack 235 includes a second plurality of dies and may be oriented at a second angle corresponding to the second slanted upper surface 270. The second die stack 235 may have a third lateral portion 275 coupled to the second slanted upper surface 270 and a fourth lateral portion 280 that overhangs from the second slanted upper surface 270.

The microcontroller 240 may also be arranged on the first substrate surface 210, and may have a flip-chip interconnect configuration. Moreover, the microcontroller 240 may arranged between the first wedge structure 220 and the second wedge structure 230. In some implementations, the second lateral portion 265 of the first die stack 225 may extend over a first lateral portion of the microcontroller 240. Additionally, or alternatively, wherein the fourth lateral portion 280 of the second die stack 235 may extend over a second lateral portion of the microcontroller 240. The second lateral portion 265 of the first die stack 225 and the microcontroller 240 may be separated by a first vertical gap D1 such that the first die stack 225 is not in contact with the microcontroller 240. The fourth lateral portion 280 of the second die stack 235 and the microcontroller 240 may be separated by a second vertical gap D2 such that the second die stack 235 is not in contact with the microcontroller 240. The microcontroller 240 may be electrically coupled to the first plurality of dies and the second plurality of dies via data channels or memory channels that are provided on and/or in the substrate 205.

The second lateral portion 265 of the first die stack 225 may extend from an edge of the first slanted upper surface 255 such that the second lateral portion 265 hangs over the first substrate surface 210. The fourth lateral portion 280 of the second die stack 235 may extend from an edge of the second slanted upper surface 270 such that the fourth lateral portion 280 hangs over the first substrate surface 210. In some implementations, the first plurality of dies of the first die stack 225 are connected in a first shingle-stack configuration to form the first die stack 225, and the second plurality of dies of the second die stack 235 may be connected in a second shingle-stack configuration to form the second die stack 235.

The first lateral portion 260 of the first die stack 225 may include a lowered lateral end that is arranged at a lower vertical distance from the first substrate surface 210. Conversely, the second lateral portion 265 of the first die stack 225 may include a raised lateral end that is arranged at a higher vertical distance from the first substrate surface 210. Bond wires 285 may be attached to the lowered lateral end of the first die stack 225. For example, one or more bond wires 285 may be attached to a lowered lateral end of each die of the first die stack 225, with the bond wire 285 of the bottom die being attached to the first substrate surface 210.

The third lateral portion 275 of the second die stack 235 may include a lowered lateral end that is arranged at a lower vertical distance from the first substrate surface 210. Conversely, the fourth lateral portion 280 of the second die stack 235 may include a raised lateral end that is arranged at a higher vertical distance from the first substrate surface 210. Bond wires 290 may be attached to the lowered lateral end of the second die stack 235. For example, one or more bond wires 290 may be attached to a lowered lateral end of each die of the second die stack 235, with the bond wire 290 of the bottom die being attached to the first substrate surface 210.

The package casing 245 may be disposed over the first substrate surface 210 such that the package casing 245 encapsulates the first die stack 225, the second die stack 235, and the microcontroller 240. The casing may also cover at least part of the first substrate surface 210.

The plurality of conductive interconnect structures 250 may be coupled to electrical contacts arranged at the second substrate surface 215, and may provide electrical connections to a circuit board.

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

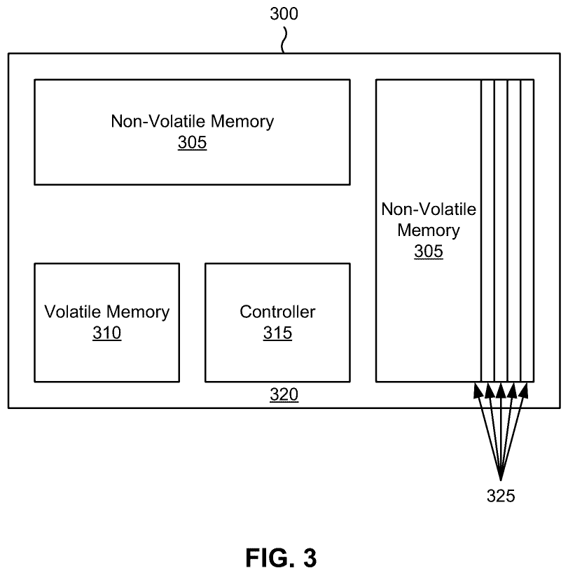

FIG. 3 is a diagram of an example memory device 300 that may be manufactured using techniques described herein. The memory device 300 is an example of the apparatus 100 described above in connection with FIG. 1. The memory device 300 may be any electronic device configured to store data in memory. In some implementations, the memory device 300 may be an electronic device configured to store data persistently in non-volatile memory 305. For example, the memory device 300 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

As shown, the memory device 300 may include non-volatile memory 305, volatile memory 310, and a controller 315. The components of the memory device 300 may be mounted on or otherwise disposed on a substrate 320. In some implementations, the non-volatile memory 305 includes a single die. Additionally, or alternatively, the non-volatile memory 305 may include multiple dies, such as stacked semiconductor dies 325 (e.g., in a straight stack, a shingle stack, or another type of stack), as described above in connection with FIG. 1.

The non-volatile memory 305 may be configured to maintain stored data after the memory device 300 is powered off. For example, the non-volatile memory 305 may include NAND memory or NOR memory. The volatile memory 310 may require power to maintain stored data and may lose stored data after the memory device 300 is powered off. For example, the volatile memory 310 may include one or more latches and/or RAM, such as DRAM and/or SRAM. As an example, the volatile memory 310 may cache data read from or to be written to non-volatile memory 305, and/or may cache instructions to be executed by the controller 315.

The controller 315 may be any device configured to communicate with the non-volatile memory 305, the volatile memory 310, and a host device (e.g., via a host interface of the memory device 300). For example, the controller 315 may include a memory controller, a system controller, an ASIC, an FPGA, a processor, a microcontroller, and/or one or more processing components. In some implementations, the memory device 300 may be included in a system that includes the host device. The host device may include one or more processors configured to execute instructions and store data in the non-volatile memory 305.

The controller 315 may be configured to control operations of the memory device 300, such as by executing one or more instructions (sometimes called commands). For example, the memory device 300 may store one or more instructions as firmware, and the controller 315 may execute those one or more instructions. Additionally, or alternatively, the controller 315 may receive one or more instructions from a host device via a host interface, and may execute those one or more instructions. For example, the controller 315 may transmit signals to and/or receive signals from the non-volatile memory 305 and/or the volatile memory 310 based on the one or more instructions, such as to transfer data to (e.g., write or program), to transfer data from (e.g., read), and/or to erase all or a portion of the non-volatile memory 305 (e.g., one or more memory cells, pages, sub-blocks, blocks, or planes of the non-volatile memory 305).

As indicated above, FIG. 3 is provided as an example. Other examples may differ from what is described with regard to FIG. 3. The number and arrangement of components shown in FIG. 3 are provided as an example. In practice, there may be additional components, fewer components, different components, or differently arranged components than those shown in FIG. 3.

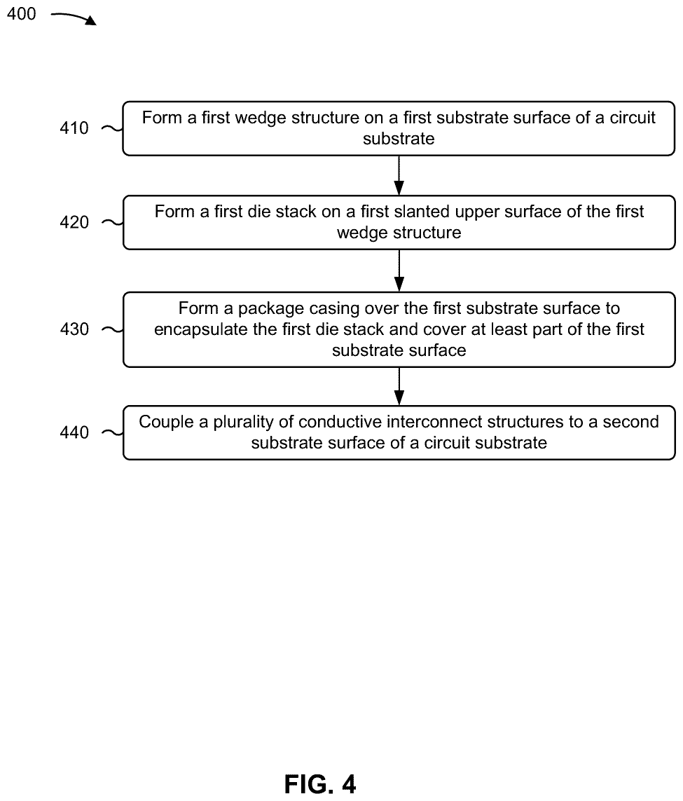

FIG. 4 is a flowchart of an example method 400 of forming an integrated assembly or memory device having a slanted die stack. In some implementations, one or more process blocks of FIG. 4 may be performed by various semiconductor manufacturing equipment.

As shown in FIG. 4, the method 400 may include forming a first wedge structure on a first substrate surface of a circuit substrate, wherein the first wedge structure has a first slanted upper surface that is slanted with respect to the first substrate surface (block 410). As further shown in FIG. 4, the method 400 may include forming a first die stack on the first slanted upper surface, wherein the first die stack comprises a first plurality of dies, wherein the first die stack is oriented at a first angle corresponding to the first slanted upper surface, and wherein the first die stack has a first lateral portion coupled to the first slanted upper surface and a second lateral portion that overhangs from the first slanted upper surface (block 420). As further shown in FIG. 4, the method 400 may include forming a package casing over the first substrate surface, wherein the package casing encapsulates the first die stack and covers at least part of the first substrate surface (block 430). As further shown in FIG. 4, the method 400 may include coupling a plurality of conductive interconnect structures to a second substrate surface of a circuit substrate, wherein the second substrate surface is arranged opposite to the first substrate surface (block 440).

The method 400 may include additional aspects, such as any single aspect or any combination of aspects described below and/or in connection with one or more other methods described elsewhere herein.

In an additional aspect, the method 400 includes forming a second wedge structure on the first substrate surface, wherein the second wedge structure has a second slanted upper surface that is slanted with respect to the first substrate surface; forming a second die stack arranged on the second slanted upper surface, wherein the second die stack comprises a second plurality of dies, wherein the second die stack is oriented at a second angle corresponding to the second slanted upper surface, and wherein the second die stack has a third lateral portion coupled to the second slanted upper surface and a fourth lateral portion that overhangs from the second slanted upper surface; and providing a microcontroller on the first substrate surface, wherein the microcontroller is arranged between the first wedge structure and the second wedge structure, and wherein the package casing encapsulates the first die stack, the second die stack, and the microcontroller.

Although FIG. 4 shows example blocks of the method 400, in some implementations, the method 400 may include additional blocks, fewer blocks, different blocks, or differently arranged blocks than those depicted in FIG. 4. In some implementations, the method 400 may include forming the apparatus 100, an integrated assembly that includes the apparatus 100, any part described herein of the structure of apparatus 100, and/or any part described herein of an integrated assembly that includes the structure of apparatus 100. In some implementations, the method 400 may include forming the semiconductor device assembly 200, an integrated assembly that includes the semiconductor device assembly 200, any part described herein of the structure of semiconductor device assembly 200, and/or any part described herein of an integrated assembly that includes the structure of semiconductor device assembly 200.

In some implementations, a semiconductor device assembly includes a circuit substrate comprising a first substrate surface and a second substrate surface arranged opposite to the first substrate surface; a wedge structure arranged on the first substrate surface, wherein the wedge structure has a slanted upper surface that is slanted with respect to the first substrate surface; a die stack arranged on the slanted upper surface, wherein the die stack comprises a plurality of dies, wherein the die stack is oriented at an angle corresponding to the slanted upper surface, and wherein the die stack has a first lateral portion coupled to the slanted upper surface and a second lateral portion that overhangs from the slanted upper surface; a package casing disposed over the first substrate surface, wherein the package casing encapsulates the die stack and covers at least part of the first substrate surface; and a plurality of conductive interconnect structures coupled to the second substrate surface.

In some implementations, a semiconductor device assembly includes a circuit substrate comprising a first substrate surface and a second substrate surface arranged opposite to the first substrate surface; a first wedge structure arranged on the first substrate surface, wherein the first wedge structure has a first slanted upper surface that is slanted with respect to the first substrate surface; a first die stack arranged on the first slanted upper surface, wherein the first die stack comprises a first plurality of dies, wherein the first die stack is oriented at a first angle corresponding to the first slanted upper surface, and wherein the first die stack has a first lateral portion coupled to the first slanted upper surface and a second lateral portion that overhangs from the first slanted upper surface; a second wedge structure arranged on the first substrate surface, wherein the second wedge structure has a second slanted upper surface that is slanted with respect to the first substrate surface; and a second die stack arranged on the second slanted upper surface, wherein the second die stack comprises a second plurality of dies, wherein the second die stack is oriented at a second angle corresponding to the second slanted upper surface, and wherein the second die stack has a third lateral portion coupled to the second slanted upper surface and a fourth lateral portion that overhangs from the second slanted upper surface; a microcontroller arranged on the first substrate surface, wherein the microcontroller is arranged between the first wedge structure and the second wedge structure; a package casing disposed over the first substrate surface, wherein the package casing encapsulates the first die stack and the second die stack, and the package casing covers at least part of the first substrate surface; and a plurality of conductive interconnect structures coupled to the second substrate surface.

In some implementations, a method of manufacturing a semiconductor device assembly includes forming a first wedge structure on a first substrate surface of a circuit substrate, wherein the first wedge structure has a first slanted upper surface that is slanted with respect to the first substrate surface; forming a first die stack on the first slanted upper surface, wherein the first die stack comprises a first plurality of dies, wherein the first die stack is oriented at a first angle corresponding to the first slanted upper surface, and wherein the first die stack has a first lateral portion coupled to the first slanted upper surface and a second lateral portion that overhangs from the first slanted upper surface; forming a package casing over the first substrate surface, wherein the package casing encapsulates the first die stack and covers at least part of the first substrate surface; and coupling a plurality of conductive interconnect structures to a second substrate surface of a circuit substrate, wherein the second substrate surface is arranged opposite to the first substrate surface.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
a circuit substrate comprising a first substrate surface and a second substrate surface arranged opposite to the first substrate surface;
a wedge structure arranged on the first substrate surface, wherein the wedge structure has a slanted upper surface that is slanted with respect to the first substrate surface;
a die stack arranged on the slanted upper surface, wherein the die stack comprises a plurality of dies, wherein the die stack is oriented at an angle corresponding to the slanted upper surface, and wherein the die stack has a first lateral portion coupled to the slanted upper surface and a second lateral portion that overhangs from the slanted upper surface;
a package casing disposed over the first substrate surface, wherein the package casing encapsulates the die stack and covers at least part of the first substrate surface; and
a plurality of conductive interconnect structures coupled to the second substrate surface.

2. The semiconductor device assembly of claim 1, wherein the second lateral portion extends from an edge of the slanted upper surface such that the second lateral portion hangs over the first substrate surface.

3. The semiconductor device assembly of claim 2, wherein a vertical distance between the die stack and first substrate surface increases as a lateral distance between the edge of the slanted upper surface to a stack edge of the second lateral portion increases.

4. The semiconductor device assembly of claim 1, wherein the plurality of dies are connected in a shingle-stack configuration to form the die stack.

5. The semiconductor device assembly of claim 4, wherein each subsequent die of the die stack is offset from a previous die of the die stack such that an amount each die of the die stack that overhangs from the slanted upper surface increases with each subsequent die.

6. The semiconductor device assembly of claim 4, wherein the die stack includes a first die and a second die,
wherein the first die is arranged on the slanted upper surface of the wedge structure and has a first overhang that extends beyond an edge of the slanted upper surface,
wherein the second die is arranged on the first die and has a second overhang that extends beyond the edge of the slanted upper surface, and
wherein the second overhang is larger than the first overhang.

7. The semiconductor device assembly of claim 1, further comprising:
a microcontroller arranged on the first substrate surface,
wherein the microcontroller is electrically coupled to the plurality of dies,
wherein the second lateral portion extends over a portion of the microcontroller, and
wherein second lateral portion and the microcontroller are separated by a vertical gap such that the die stack is not in contact with the microcontroller.

8. The semiconductor device assembly of claim 7, wherein the microcontroller has a flip-chip interconnect configuration.

9. The semiconductor device assembly of claim 7, wherein the plurality of dies are memory dies and the microcontroller is a memory controller.

10. The semiconductor device assembly of claim 9, wherein the memory dies are NAND memory dies or dynamic random-access memory (DRAM) memory dies.

11. The semiconductor device assembly of claim 1, wherein the wedge structure is made from a molding material.

12. A semiconductor device assembly, comprising:
a circuit substrate comprising a first substrate surface and a second substrate surface arranged opposite to the first substrate surface;
a first wedge structure arranged on the first substrate surface, wherein the first wedge structure has a first slanted upper surface that is slanted with respect to the first substrate surface;
a first die stack arranged on the first slanted upper surface, wherein the first die stack comprises a first plurality of dies, wherein the first die stack is oriented at a first angle corresponding to the first slanted upper surface, and wherein the first die stack has a first lateral portion coupled to the first slanted upper surface and a second lateral portion that overhangs from the first slanted upper surface;
a second wedge structure arranged on the first substrate surface, wherein the second wedge structure has a second slanted upper surface that is slanted with respect to the first substrate surface;
a second die stack arranged on the second slanted upper surface, wherein the second die stack comprises a second plurality of dies, wherein the second die stack is oriented at a second angle corresponding to the second slanted upper surface, and wherein the second die stack has a third lateral portion coupled to the second slanted upper surface and a fourth lateral portion that overhangs from the second slanted upper surface;
a microcontroller arranged on the first substrate surface, wherein the microcontroller is arranged between the first wedge structure and the second wedge structure;
a package casing disposed over the first substrate surface, wherein the package casing encapsulates the first die stack and the second die stack, and the package casing covers at least part of the first substrate surface; and
a plurality of conductive interconnect structures coupled to the second substrate surface.

13. The semiconductor device assembly of claim 12, wherein the second lateral portion extends over a first lateral portion of the microcontroller, and
wherein the fourth lateral portion extends over a second lateral portion of the microcontroller.

14. The semiconductor device assembly of claim 12, wherein the second lateral portion and the microcontroller are separated by a first vertical gap such that the first die stack is not in contact with the microcontroller, and
wherein the fourth lateral portion and the microcontroller are separated by a second vertical gap such that the second die stack is not in contact with the microcontroller.

15. The semiconductor device assembly of claim 12, wherein the second lateral portion extends from an edge of the first slanted upper surface such that the second lateral portion hangs over the first substrate surface, and
wherein the fourth lateral portion extends from an edge of the second slanted upper surface such that the fourth lateral portion hangs over the first substrate surface.

16. The semiconductor device assembly of claim 12, wherein the first plurality of dies are connected in a first shingle-stack configuration to form the first die stack, and
wherein the second plurality of dies are connected in a second shingle-stack configuration to form the second die stack.

17. The semiconductor device assembly of claim 12, wherein the microcontroller has a flip-chip interconnect configuration.

18. The semiconductor device assembly of claim 12, wherein the microcontroller is electrically coupled to the first plurality of dies and the second plurality of dies via data channels or memory channels.

19. A method of manufacturing a semiconductor device assembly, the method comprising:
forming a first wedge structure on a first substrate surface of a circuit substrate, wherein the first wedge structure has a first slanted upper surface that is slanted with respect to the first substrate surface;
forming a first die stack on the first slanted upper surface, wherein the first die stack comprises a first plurality of dies, wherein the first die stack is oriented at a first angle corresponding to the first slanted upper surface, and wherein the first die stack has a first lateral portion coupled to the first slanted upper surface and a second lateral portion that overhangs from the first slanted upper surface;
forming a package casing over the first substrate surface, wherein the package casing encapsulates the first die stack and covers at least part of the first substrate surface; and
coupling a plurality of conductive interconnect structures to a second substrate surface of a circuit substrate, wherein the second substrate surface is arranged opposite to the first substrate surface.

20. The method of claim 19, further comprising:
forming a second wedge structure on the first substrate surface, wherein the second wedge structure has a second slanted upper surface that is slanted with respect to the first substrate surface;
forming a second die stack arranged on the second slanted upper surface, wherein the second die stack comprises a second plurality of dies, wherein the second die stack is oriented at a second angle corresponding to the second slanted upper surface, and wherein the second die stack has a third lateral portion coupled to the second slanted upper surface and a fourth lateral portion that overhangs from the second slanted upper surface; and
providing a microcontroller on the first substrate surface, wherein the microcontroller is arranged between the first wedge structure and the second wedge structure,
wherein the package casing encapsulates the first die stack, the second die stack, and the microcontroller.
